(19) United States
(12) Patent Application Publication
(10) Pub. No.: US 2017/0154933 A1
(43) Pub. Date: Jun. 1, 2017

(54) DISPLAY PANEL AND METHOD FOR MANUFACTURING THE SAME, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Ziwei CUI, Beijing (CN); Hongyan XING, Beijing (CN); Jing XUE, Beijing (CN); Yanyan YIN, Beijing (CN)

(21) Appl. No.: 15/122,197

(22) PCT Filed: Jan. 6, 2016
(86) PCT No.: PCT/CN2016/070224

§ 371 Date: Aug. 29, 2016

(30) Foreign Application Priority Data
Jul. 28, 2015 (CN) 201510450531.5

(51) Int. Cl. H01L 27/32

(52) U.S. Cl. CPC H01L 27/3227; H01L 27/3248

(57) ABSTRACT

The present invention relates to a display panel and a method for manufacturing the same, and a display device. The display panel includes a display region and a non-display region, wherein a photovoltaic cell component is provided in the non-display region and is used to generate electricity when being irradiated by light. The photovoltaic cell component generates electricity when being irradiated by light, and the electricity can be provided to the display panel for the use of display or other functions, thereby supplementing electricity of the power supply, improving the utilization of energy, and prolonging the endurance time of the display panel in a case where the power supply used for providing electricity to the display panel has limited capacity.

### FIELD OF THE INVENTION

The present invention relates to the field of display technology, and specifically relates to a display panel and a method for manufacturing the same, and a display device.

### BACKGROUND OF THE INVENTION

A display device requires a power supply for providing electricity thereto so as to implement the display of an image. Specifically, for a thin film transistor liquid crystal display (hereinafter referred to as a TFT-LCD), in order to implement the display of an image, a power supply is needed to provide electricity to a backlight source so as to allow the backlight source to emit light, and is also needed to provide electricity to a display panel, so that a chip is driven to generate signals, a device such as a thin film transistor or the like is driven to operate, and an electric field for deflecting liquid crystal molecules is generated. For an organic light-emitting diode (OLED) display, in order to implement the display of an image, a power supply is needed to provide electricity to devices such as thin film transistors and the like so as to turn on or turn off light-emitting devices, and is also needed to provide electricity to the light-emitting devices, so as to allow the light-emitting devices to emit light.

For conventional display panels and devices, electricity is totally provided by a power supply, and the display panels and devices cannot generate electricity by themselves to be a supplementary of the power supply. Therefore, in a case where power supply has limited capacity, the display device has limited endurance time.

### SUMMARY OF THE INVENTION

The present invention is intended to solve at least one of the technical problems existing in the prior art, and provides a display panel and a method for manufacturing the same, and a display device, wherein the display panel can generate electricity for the use of display or other functions, so that electricity that the power supply needs to supply to the display panel can be supplemented, thereby increasing endurance time of the display panel.

To achieve the object of the present invention, there is provided a display panel comprising a display region and a non-display region, wherein a photovoltaic cell component is provided in the non-display region and is used to generate electricity when being irradiated by light.

Optionally, the photovoltaic cell component is electrically connected to a power supply used for providing electricity to the display panel, and charges the power supply when generating electricity.

Optionally, the photovoltaic cell component includes at least one P-N junction unit, and when the P-N junction unit is irradiated by light, electrons are generated in a P-type region of the P-N junction unit and holes are generated in an N-type region of the P-N junction unit.

Optionally, the P-type region of the P-N junction unit includes at least one of P-doped Si, SiGe and GaAs, and the N-type region of the P-N junction unit includes at least one of N-doped Si, SiGe and GaAs.

Optionally, the P-N junction unit has a P-N-P structure including a base electrode, a collector electrode and an emitter electrode.

As another embodiment, the present invention also provides a method for manufacturing the above display panel, which includes a step of manufacturing the photovoltaic cell component in the non-display region of the display panel.

Optionally, the step of manufacturing the photovoltaic cell component includes:
providing a base substrate;
forming, on the base substrate, a pattern of a P-doped collector electrode;
forming, on the pattern of the collector electrode, a pattern of an N-doped base electrode;
forming an insulating layer on the pattern of the base electrode; and
forming, on the insulating layer, a pattern of a P-doped emitter electrode.

Optionally, material of the collector electrode includes at least one of P-doped Si, SiGe and GaAs, material of the base electrode includes at least one of N-doped Si, SiGe and GaAs, material of the insulating layer includes SiO₂, and material of the emitter electrode includes at least one of P-doped Si, SiGe and GaAs.

As another embodiment, the present invention also provides a display device including the above display panel provided by the present invention.

Optionally, the display device is an OLED display device, and light irradiating the photovoltaic cell component includes ambient light and/or light emitted by an OLED device of the OLED display device.

Optionally, the display device is a liquid crystal display device, and light irradiating the photovoltaic cell component includes ambient light and/or light emitted by a backlight source of the liquid crystal display device.

Beneficial effects of the present invention are as follows.

According to the display panel provided by the present invention, the photovoltaic cell component is provided in an area of the non-display region upon which light can impinge, and generates electricity when being irradiated by light, and the electricity can be provided to the display panel for the use of display or other functions. With such arrangement, electricity of the power supply can be supplemented, the utilization of energy can be improved, and in a case where the power supply used for providing electricity to the display panel has limited capacity, the endurance time of the display panel can be prolonged.

According to the method for manufacturing the display panel provided by the present invention, the photovoltaic cell component is manufactured in the non-display region of the display panel, and generates electricity when being irradiated by light, and the electricity can be provided to the display panel for the use of display or other functions. With such arrangement, electricity of the power supply can be supplemented, the utilization of energy can be improved, and in a case where the power supply used for providing electricity to the display panel has limited capacity, the endurance time of the display panel can be prolonged.

According to the display device provided by the present invention, the above display panel provided by the present invention is employed so as to generate electricity for the use of display or other functions. With such arrangement, electricity of the power supply can be supplemented, the utilization of energy can be improved, and in a case where the power supply used for providing electricity to the display panel has limited capacity, the endurance time of the display panel can be prolonged.

### BRIEF DESCRIPTION OF THE DRAWINGS

The accompanying drawings, which constitute a part of the specification, are provided for a further understanding of the present invention, and for explaining the present invention together with the following specific embodiments, but not intended to limit the present invention. In the drawings:

FIG. 1 is a schematic diagram of a display panel according to an embodiment of the present invention;

FIG. 2 is a schematic diagram of a photovoltaic cell component according to an embodiment of the present invention; and

FIG. 3 is an equivalent circuit diagram of the P-N junction unit shown in FIG. 2.

### REFERENCE NUMERALS

1. display region; 2. non-display region; 3. photovoltaic cell component; 10. base substrate; 11. collector electrode; 12. base electrode; 13. insulating layer; and 14. emitter electrode.

### DETAILED DESCRIPTION OF THE EMBODIMENTS

Specific embodiments of the present invention will be described below in detail in conjunction with the accompanying drawings. It should be understood that the specific embodiments to be described herein are only intended to illustrate and explain the present invention, but not to limit the present invention.

Embodiments of the present invention provide a display panel, and FIG. 1 is a schematic diagram of a display panel according to an embodiment of the present invention. As shown in FIG. 1, the display panel includes a display region 1 and a non-display region 2, wherein a photovoltaic cell component 3 is provided in the non-display region 2 and is used to generate electricity when being irradiated by light. Light irradiating the photovoltaic cell component 3 may include ambient light from the environment. In addition, in a case of a liquid crystal display device, the light irradiating the photovoltaic cell component 3 may further include light emitted by a backlight source of the liquid crystal display device, and in a case of an OLED display device, the light irradiating the photovoltaic cell component 3 may further include light emitted by an OLED device of the OLED display device.

The photovoltaic cell component 3 is provided in an area of the non-display region 2 upon which light can impinge. With such arrangement, on one hand, the photovoltaic cell component 3 can be prevented from disturbing the image display of the display panel, thereby ensuring the same display effect of the display panel provided by the embodiment of the present invention as that of a conventional display panel when displaying an image; on the other hand, electricity can be generated and provided to the display panel. Specifically, the photovoltaic cell component 3 may be electrically connected to a power supply used for providing electricity to the display panel, and may charge the power supply when the photovoltaic cell component 3 generates electricity, and then the electricity is provided to the display panel through the power supply. Compared to the prior art, the display panel according to the embodiment generates electricity during display, and the electricity is provided to the display panel for the use of display or other functions, so electricity of the power supply can be supplemented, the utilization of energy can be improved, and in a case where the power supply has limited capacity in providing electricity, endurance time of the display panel can be prolonged.

Specifically, the photovoltaic cell component 3 includes at least one P-N junction unit, and when the PA junction unit is irradiated by light, electrons are generated in a P-type region of the P-N junction unit and holes are generated in an N-type region of the P-N junction unit so as to form electron-hole pairs. Under the electric field of the P-N junction, holes flow to the P-type region and electrons flow to the N-type region, thus forming a current flow, and when the photovoltaic cell component 3 is electrically connected to the power supply, the current flow flows into the power supply to charge the power supply.

Further, the P-type region of the P-N junction unit includes at least one of P-doped Si, SiGe and GaAs, and the N-type region of the P-N junction unit includes at least one of N-doped Si, SiGe and GaAs.

The P-N junction unit may have a P-N-P structure including a base electrode, a collector electrode and an emitter electrode, but the present inventive concept is not united thereto.

According to the display panel provided by the embodiments of the present invention, the photovoltaic cell component 3 is provided in the non-display region 2, and generates electricity when being irradiated by light, the generated electricity can be provided to the display panel for the use of display or other functions. With such arrangement, electricity of the power supply can be supplemented, the utilization of energy can be improved, and in a case where the power supply used for providing electricity to the display panel has limited capacity, the endurance time of the display panel can be prolonged.

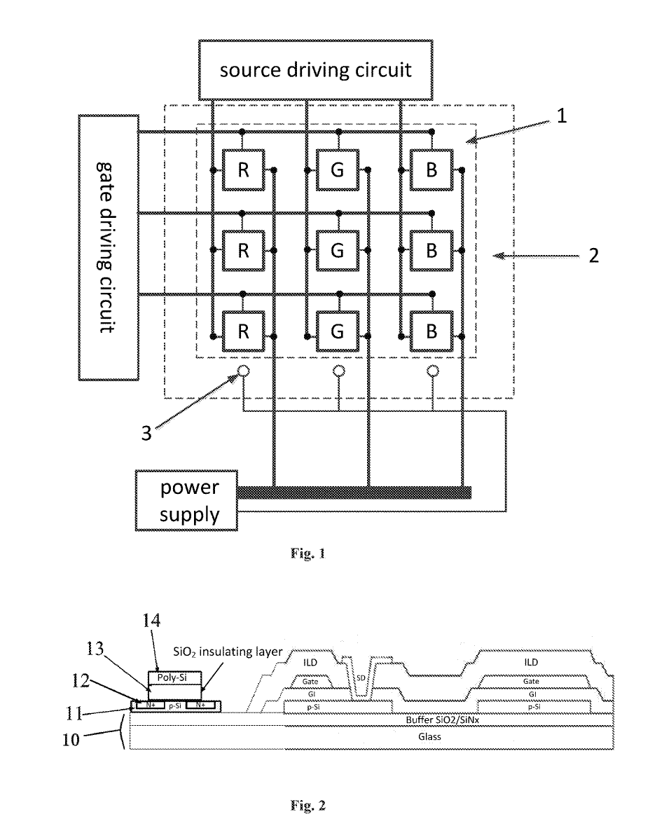

The present invention further provides an implementation of a method for manufacturing the above display panel, which includes a step of manufacturing the photovoltaic cell component in the non-display region of the display panel. The photovoltaic cell component formed by using the method is as shown in FIG. 2.

The method may further include steps of manufacturing a thin film transistor and various signal lines, and the sequence of the steps is not limited. For example, in practice, the step of manufacturing the photovoltaic cell component may be performed after a step of manufacturing the thin film transistor; or, the step of manufacturing the thin film transistor may be performed after the step of manufacturing the photovoltaic cell component.

Specifically, the step of manufacturing the photovoltaic cell component includes:
providing a base substrate 10;
forming, on the base substrate 10, a pattern of a P-doped collector electrode 11;
forming, on the pattern of the collector electrode 11, a pattern of an N-doped base electrode 12;
forming an insulating layer 13 on the pattern of the base electrode 12; and
forming, on the insulating layer 13, a pattern of a P-doped emitter electrode 14.

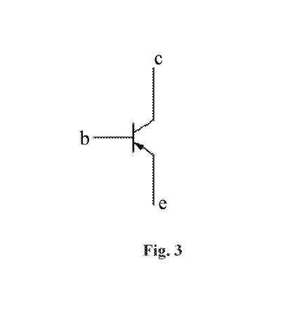

According to the above steps, the photovoltaic cell component shown in FIG. 2 can be formed. The formed P-N junction unit has a P-N-P structure, of which the equivalent circuit is as shown in FIG. 3. In FIG. 3, “b”, “c” and “e” represent the base electrode 12, the collector electrode 11 and the emitter electrode 14, respectively.

Further, material of the collector electrode 11 includes at least one of P-doped Si, SiGe and GaAs, material of the base electrode 12 includes at least one of N-doped Si, SiGe and GaAs, material of the insulating layer 13 includes SiO₂, and material of the emitter electrode 14 includes at least one of P-doped Si, SiGe and GaAs.

According to the method for manufacturing the display panel provided by this embodiment, the photovoltaic cell component is manufactured in the non-display region of the display panel, and generates electricity when being irradiated by light, and the generated electricity can be provided to the display panel for the use of display or other functions. With such arrangement, electricity of the power supply can be supplemented, the utilization of energy can be improved, and in a case where the power supply used for providing electricity to the display panel has limited capacity, the endurance time of the display panel can be improved.

Embodiments of the present invention further provide an implementation of a display device, which includes the display panel according to the above embodiment of the present invention.

Specifically, the display device may be an OLED display device. In this case, light irradiating the photovoltaic cell component may include ambient light and/or light emitted by an OLED device of the OLED display device. For the OLED display device, the non-display region thereof has a large available space which may facilitate the manufacture of a large amount of photovoltaic cell components, and thus is beneficial to the generation of more electricity.

Alternatively, the display device may be a liquid crystal display device. In this case, light irradiating the photovoltaic cell component may include ambient light and/or light emitted by a backlight source of the liquid crystal display device. For the liquid crystal display device, a large amount of light is emitted from the backlight source, so the photovoltaic cell component provided in the non-display region can receive sufficient light, which is beneficial to the generation of more electricity.

According to the display device provided by the embodiment of the present invention, the display panel provided by the above embodiment of the present invention is employed so as to generate electricity for the use of display or other functions. With such arrangement, electricity of the power supply can be supplemented, the utilization of energy can be improved, and in a case where the power supply used for providing electricity to the display panel has limited capacity, the endurance time of the display panel can be prolonged.

It can be understood that the foregoing embodiments are merely exemplary embodiments used for describing the principle of the present invention, but the present invention is not limited thereto. Those of ordinary skill in the art may make various variations and improvements without departing from the spirit and essence of the present invention, and these variations and improvements shall fall into the protection scope of the present invention.

1-11. (canceled)

12. A display panel, comprising a display region and a non-display region, wherein a photovoltaic cell component is provided in the non-display region and is used to generate electricity when being irradiated by light.

13. The display panel according to claim 12, wherein the photovoltaic cell component is electrically connected to a power supply used for providing electricity to the display panel, and charges the power supply when generating electricity.

14. The display panel according to claim 12, wherein the photovoltaic cell component includes at least one P-N junction unit, and when the P-N junction unit is irradiated by light, electrons are generated in a P-type region of the P-N junction unit and holes are generated in an N-type region of the P-N junction unit.

15. The display panel according to claim 13, wherein the photovoltaic cell component includes at least one P-N junction unit, and when the P-N junction unit is irradiated by light, electrons are generated in a P-type region of the P-N junction unit and holes are generated in an N-type region of the P-N junction unit.

16. The display panel according to claim 14, wherein the P-type region of the P-N junction unit includes at least one of P-doped Si, SiGe and GaAs, and the N-type region of the P-N junction unit includes at least one of N-doped Si, SiGe and GaAs.

17. The display panel according to claim 15, wherein the P-type region of the P-N junction unit includes at least one of P-doped Si, SiGe and GaAs, and the N-type region of the P-N junction unit includes at least one of N-doped Si, SiGe and GaAs.

18. The display panel according to claim 14, wherein the P-N junction unit has a P-N-P structure including a base electrode, a collector electrode and an emitter electrode.

19. The display panel according to claim 15, wherein the P-N junction unit has a P-N-P structure including a base electrode, a collector electrode and an emitter electrode.

20. A method for manufacturing the display panel according to claim 12, including a step of manufacturing the photovoltaic cell component in the non-display region of the display panel.

21. The method according to claim 20, wherein the step of manufacturing the photovoltaic cell component includes:
providing a base substrate;
forming, on the base substrate, a pattern of a P-doped collector electrode;
forming, on the pattern of the collector electrode, a pattern of an N-doped base electrode;
forming an insulating layer on the pattern of the base electrode; and
forming, on the insulating layer, a pattern of a P-doped emitter electrode.

22. The method according to claim 21, wherein material of the collector electrode includes at least one of P-doped Si, SiGe and GaAs, material of the base electrode includes at least one of N-doped Si, SiGe and GaAs, material of the insulating layer includes SiO₂, and material of the emitter electrode includes at least one of P-doped Si, SiGe and GaAs.

23. A display device, including the display panel according claim 12.

24. The display device according to claim 23, wherein the display device is an organic light-emitting diode display device, and light irradiating the photovoltaic cell component includes ambient light and/or light emitted by an organic light-emitting diode device in the organic light-emitting diode display device.

25. The display device according to claim 23, wherein the display device is a liquid crystal display device, and light irradiating the photovoltaic cell component includes ambient light and/or light emitted by a backlight source of the liquid crystal display device.
